(19) United States
(12) Patent Application Publication
(10) Pub. No.: US 2026/0324482 A1
(43) Pub. Date: Oct. 15, 2026

(54) SEMICONDUCTOR PACKAGES AND METHODS OF FORMING THE SAME

(71) Applicant: TAIWAN SEMICONDUCTOR MANUFACTURING COMPANY, LTD., Hsinchu (TW)

(72) Inventors: Li-An WEN, Hsinchu (TW); Yi Chen HO, Taichung (TW)

(21) Appl. No.: 19/177,681

(22) Filed: Apr. 14, 2025

(51) Int. Cl. H01L 23/00

(52) U.S. Cl. CPC H10W 72/073; H10W 72/0711; H10W 72/072; H10W 99/00; H10W 72/07173; H10W 72/07338; H10W 72/07341; H10W 72/241

(57) ABSTRACT

Embodiments discussed herein relate to methods of forming underfill structures in various semiconductor packages. In some embodiments, the underfill structures may be applied to a device package with reduced air bubbles. In some embodiments, an oscillation may be performed after application and prior to curing of the underfill material to remove air bubbles in the underfill material. In some embodiments, the oscillation process comprises applying an oscillating pressure. In some embodiments, the oscillation process comprises applying an acoustic oscillation. In some embodiments, the acoustic oscillation is performed in combination with the pressure oscillation.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for forming a semiconductor device package according to embodiments of the present disclosure.

FIGS. 2-6, 7A-7D, 8A-81, and 9-10 illustrate intermediary stages of manufacturing a semiconductor device package in accordance with some embodiments.

FIG. 11 is a flow chart of a method for forming a semiconductor device package according to embodiments of the present disclosure.

FIGS. 12, 13A-13F, and 14 illustrate intermediary stages of manufacturing a semiconductor device package in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the semiconductor device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein relate to methods of forming underfill structures in various semiconductor packages. In some embodiments, the underfill structures may be applied to a device package with reduced air bubbles. In some embodiments, an oscillation may be performed after application and prior to curing of the underfill material to remove air bubbles in the underfill material. In some embodiments, the oscillation process comprises applying an oscillating pressure. In some embodiments, the oscillation process comprises applying an acoustic oscillation, a mechanical oscillation, or the like. In some embodiments, the acoustic oscillation is performed in combination with the pressure oscillation.

In some embodiments, the underfill structures may be applied to a package structure (e.g., a package on package (POP) structure) including a first package component and a second package component. The second package component may be a memory package (e.g., having one or more dynamic random access memory (DRAM) dies), which is physically and electrically coupled to the first package component (e.g., an integrated fan-out (InFO) package having a logic die and redistribution structures) using functional connectors. In some embodiments, the underfill structures may be applied to a device package comprising one or more semiconductor chips bonded to an interposer and a package substrate bonded to a side of the interposer opposing the one or more semiconductor chips. The device package may be referred to a chip-on-wafer-on-substrate (CoWoS™ package) ultra-thin sandwich (UTS) package.

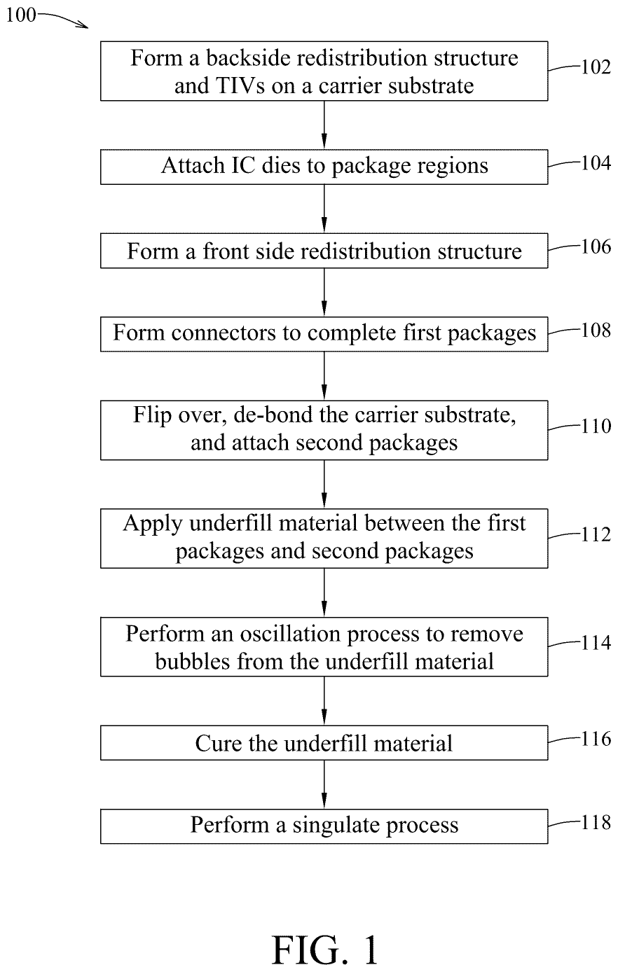

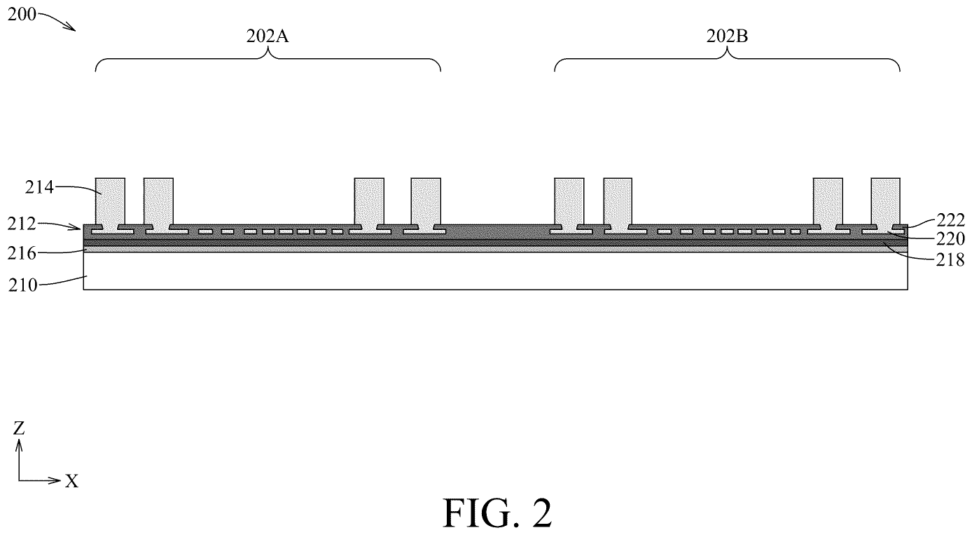

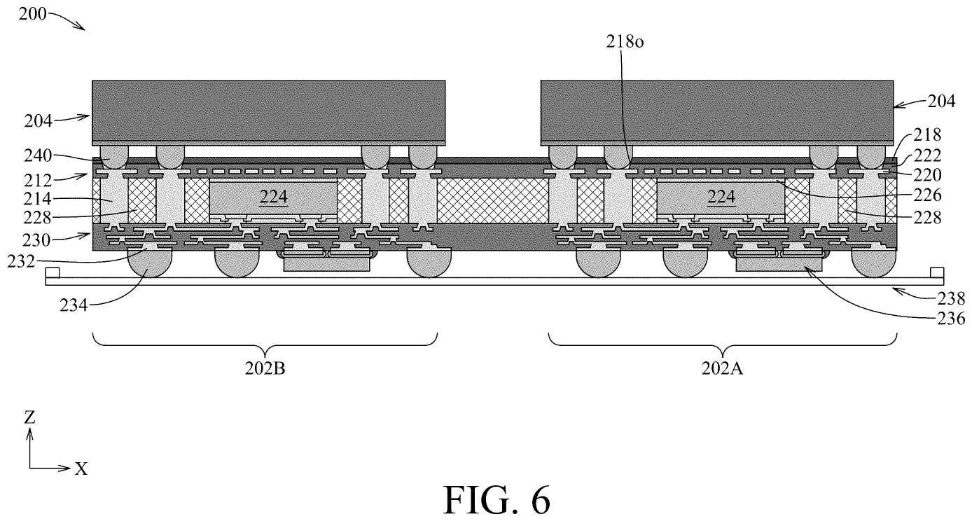

FIG. 1 is a flow chart of a method 100 for forming a semiconductor device package according to embodiments of the present disclosure. FIGS. 2-6, 7A-7D, 8A-8G, and 9-10 illustrate intermediary stages of manufacturing a semiconductor device package 200 in accordance with some embodiments. The semiconductor device package 200 may be fabricated using the method 100. The semiconductor device package 200 may also be referred to as an integrated fan-out package-on-package (InFO-POP) package. The semiconductor device package 200 includes a first package 202 and a second package 204 mounted on the first package 202. In FIGS. 2-5, a plurality of the first packages 202, which may be referred to as an integrated fan-out (InFO) package, are formed. In FIGS. 6-9, a plurality of the second packages 204 are mounted to the plurality of first package 202 with underfill material formed in between to form the semiconductor device package 200.

In operation 102 of the method 100, a backside redistribution structure 212 and through vias 214 are formed, as shown in FIG. 2. FIG. 2 is a schematic partial cross sectional view of the semiconductor device package 200.

The carrier substrate 210 may be a glass carrier substrate, a ceramic carrier substrate, or the like. The carrier substrate 210 may be a wafer, such that multiple packages can be formed on the carrier substrate 210 simultaneously. A release layer 216 may be formed of a polymer-based material, which may be removed along with the carrier substrate 210 from the overlying structures that will be formed in subsequent steps. In some embodiments, the release layer 216 is an epoxy-based thermal-release material, which loses its adhesive property when heated, such as a light-to-heat-conversion (LTHC) release coating. In other embodiments, the release layer 216 may be an ultra-violet (UV) glue, which loses its adhesive property when exposed to UV lights. The release layer 216 may be dispensed as a liquid and cured, may be a laminate film laminated onto the carrier substrate 210, or may be the like. The top surface of the release layer 216 may be leveled and may have a high degree of coplanarity.

A polymer buffer layer 218 is then formed over the top surface of the release layer 216. In some embodiments, the polymer buffer layer 218 is formed of a polymer, such as polybenzoxazole (PBO), polyimide, benzocyclobutene (BCB), or the like. The polymer buffer layer 218 may be formed by any acceptable deposition process, such as spin coating, chemical vapor deposition (CVD), laminating, the like, or a combination thereof.

The backside redistribution structure 212 is then formed over the polymer buffer layer 218. The backside redistribution structure 212 may include one or more layers of metallization pattern 220 embedded in one or more dielectric layers 222.

As an example, to form metallization pattern 220, a seed layer (not separately illustrated) is formed over the polymer buffer layer 218. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 220. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 220.

The dielectric layer 222 is formed on or around the metallization pattern 220. In some embodiments, the dielectric layer 222 is formed of a polymer, which may be a photo-sensitive material such as PBO, polyimide, BCB, or the like, that may be patterned using a lithography mask. In other embodiments, the dielectric layer 222 is formed of a nitride such as silicon nitride; an oxide such as silicon oxide, PSG, BSG, BPSG; or the like. The dielectric layer1102 may be formed by spin coating, lamination, CVD, the like, or a combination thereof. The dielectric layer 222 is then patterned to form openings to expose portions of the metallization pattern 220. The patterning may be by an acceptable process, such as by exposing the dielectric layer 222 to light when the dielectric layer is a photo-sensitive material or by etching using, for example, an anisotropic etch.

The polymer buffer layer 218, the dielectric layer 222 and the metallization pattern 220 may be referred to as the backside redistribution structure 212. As illustrated in FIG. 2, the backside redistribution structure 212 includes the polymer buffer layer 218, the dielectric layer 222, and one metallization pattern 220. In other embodiments, the backside redistribution structure 212 can include any number of dielectric layers, metallization patterns, and vias. One or more additional metallization pattern 220 and dielectric layers 222 may be formed in the backside redistribution structure 212 by repeating the processes for forming a metallization pattern 220 and dielectric layer 222. Vias may be formed during the formation of a metallization pattern by forming the seed layer and conductive material of the metallization pattern in the opening of the underlying dielectric layer. The vias may therefore interconnect and electrically couple the various metallization patterns.

Through vias 214 are then formed over the backside redistribution structure 212. The through vias 214 may be formed by forming a seed layer (not separately illustrated) over the backside redistribution structure 212, e.g., the dielectric layer 222 and the exposed portions of the metallization pattern 220 as illustrated. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is formed and patterned on the seed layer. The photoresist may be formed by spin coating or the like and may be exposed to light for patterning. The pattern of the photoresist corresponds to through vias. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the through vias 214.

In some embodiments, the backside redistribution structure 212 and the through vias 214 may be arranged to form a plurality of package regions over the carrier substrate 210 to form a plurality of the first packages 202. In FIG. 2, two package regions 202A and 202B are shown for example.

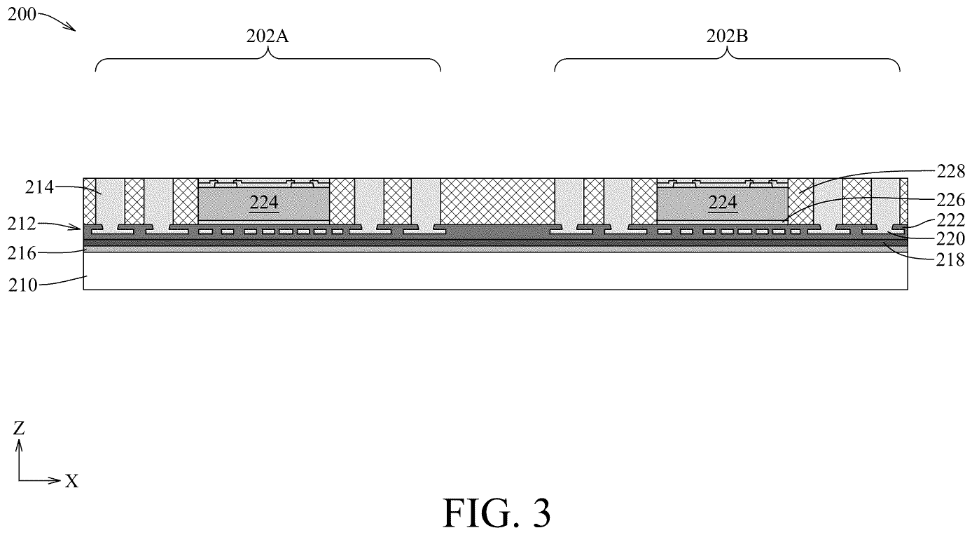

In operation 104 of the method 100, integrated circuit dies 224 are attached, as shown in FIG. 3. The integrated circuit dies 224 are adhered to the dielectric layer 222 through an adhesive layer 226. An encapsulant layer 228 is formed around the various components.

As illustrated in FIG. 3, one integrated circuit die 224 is adhered in each of the package region 202A, 202B. However, in other embodiments, more or less integrated circuit dies 224 may be adhered in each package region. For example, in some embodiments, two or more integrated circuit dies 224 may be adhered in each package region 202A, 202B. The integrated circuit dies 224 may be logic dies (e.g., central processing unit, microcontroller, etc.), memory dies (e.g., dynamic random access memory (DRAM) die, static random access memory (SRAM) die, etc.), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof. Also, in some embodiments, the integrated circuit dies 224 may be different sizes (e.g., different heights and/or surface areas), and in other embodiments, the integrated circuit dies 224 may be the same size (e.g., same heights and/or surface areas).

The adhesive layer 226 is on back-sides of the integrated circuit dies 224 and adheres the integrated circuit dies 224 to the backside redistribution structure 212, such as the dielectric layer 222 in the illustration. The adhesive layer 226 may be any suitable adhesive, epoxy, die attach film (DAF), or the like. The adhesive layer 226 may be applied to backsides of the integrated circuit dies 224, such as to a backside of a respective semiconductor wafer or may be applied over the surface of a carrier substrate of the integrated circuit dies 224. The integrated circuit dies 224 may be adhered to the dielectric layer 222 by the adhesive layer 226 using, for example, a pick-and-place tool.

The encapsulant layer 228 may then be formed on the various components. The encapsulant layer 228 may be a molding compound, epoxy, or the like, and may be applied by compression molding, transfer molding, or the like. After curing, the encapsulant layer 228 can undergo a grinding process to expose the through vias 214 and top surfaces of the integrated circuit dies 224. Following the grinding process, top surfaces of the through vias 214, the integrated circuit dies 224, and the encapsulant layer 228 may be co-planar. In some embodiments, the grinding may be omitted, for example, if through vias 214 and top surfaces of the integrated circuit dies 224 are already exposed.

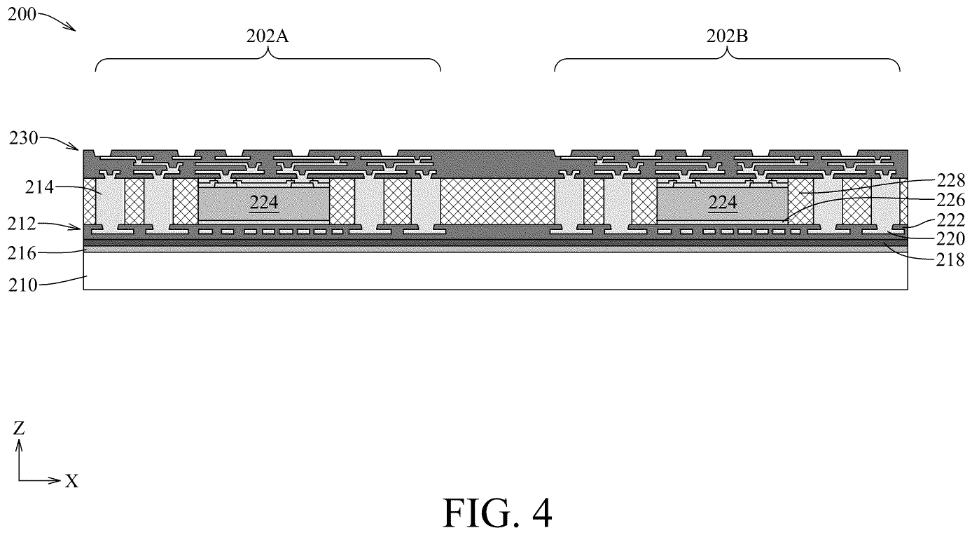

In operation 106 of the method 100, a front-side redistribution structure 230 is formed as shown in FIG. 4. The front-side redistribution structure 230 includes various dielectric layers and metallization patterns (not separately labeled), sometimes referred to as redistribution layers or redistribution lines. The dielectric layers may be formed of a polymer, which may be a photo-sensitive material such as PBO, polyimide, BCB, or the like, that may be patterned using a lithography mask. In other embodiments, the dielectric layers are formed of a nitride such as silicon nitride; an oxide such as silicon oxide, PSG, BSG, BPSG; or the like. The dielectric layers may each be formed by spin coating, lamination, CVD, the like, or a combination thereof. The dielectric layers are then patterned. The patterning forms openings in each of the dielectric layers to expose portions of the through vias 214 and top surfaces of the integrated circuit dies 224 or underlying metallization patterns. The patterning may be by an acceptable process, such as by exposing the respective dielectric layer to light when the dielectric layer is a photo-sensitive material or by etching using, for example, an anisotropic etch. If the dielectric layer is a photo-sensitive material, the dielectric layer can be developed after the exposure.

After each of the dielectric layers is formed, a metallization pattern may be formed on the respective dielectric layer. For example, to form one of the metallization patterns, a seed layer (not separately illustrated) is formed over the dielectric layer and in openings through the dielectric layer. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern and vias. The vias are formed in openings through the dielectric layer to, e.g., the through vias 214, top surfaces of the integrated circuit dies 224, and/or the underlying metallization patterns.

The front-side redistribution structure 230 is shown as an example. More or fewer dielectric layers and metallization patterns may be formed in the front-side redistribution structure 230. If fewer dielectric layers and metallization patterns are to be formed, steps and process discussed above may be omitted. If more dielectric layers and metallization patterns are to be formed, steps and processes discussed above may be repeated. One having ordinary skill in the art will readily understand which steps and processes would be omitted or repeated.

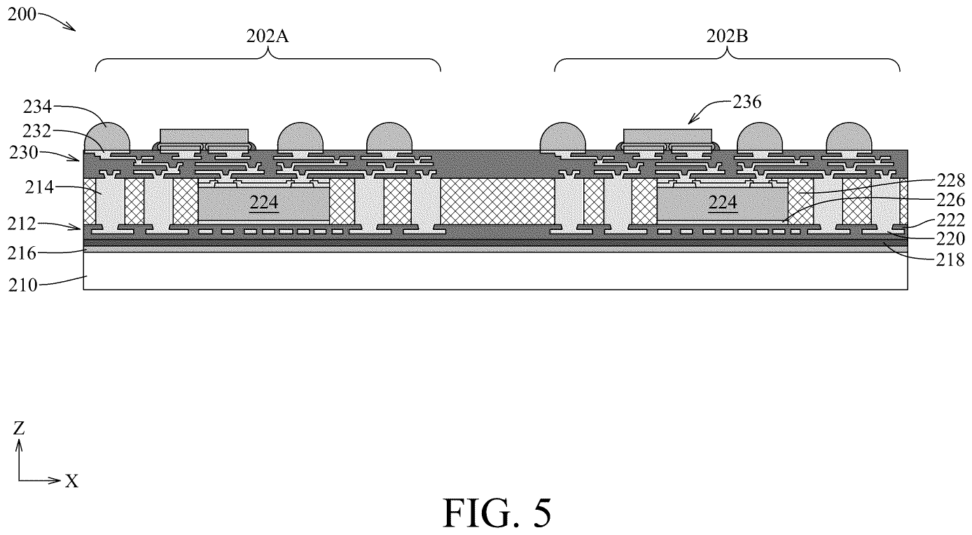

In operation 108 of the method 100, contact pads 232 are formed on an exterior side of the front-side redistribution structure 230 and conductive connectors 234 are formed on the contact pads 232 as shown in FIG. 5.

The contact pads 232 are used to couple to the conductive connectors 234 and may be referred to as under bump metallurgies (UBMs). In the illustrated embodiment, the contact pads 232 are formed through openings through the topmost dielectric layer to the topmost metallization pattern. For example, to form the contact pads 232, a seed layer (not separately illustrated) is formed over the topmost dielectric layer. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the contact pads 232. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the contact pads 232. In the embodiment, where the contact pads 232 are formed differently, more photoresist and patterning steps may be utilized.

The conductive connectors 234 are formed on the contact pads 232. The conductive connectors 234 may be BGA connectors, solder balls, metal pillars, controlled collapse chip connection (C4) bumps, micro bumps, electroless nickel-electroless palladium-immersion gold technique (ENEPIG) formed bumps, or the like. The conductive connectors 234 may include a conductive material such as solder, copper, aluminum, gold, nickel, silver, palladium, tin, the like, or a combination thereof. In some embodiments, the conductive connectors 234 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 234 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the conductive connectors1302. The metal cap layer may include nickel, tin, tin-lead, gold, silver, palladium, indium, nickel-palladium-gold, nickel-gold, the like, or a combination thereof and may be formed by a plating process.

In some embodiments, integrated passive devices (IPDs) 236 may be formed on the front-side redistribution structure 230 to achieve desirable function. The circuit components may be fabricated during formation of the conductive connectors 234. The integrated passive devices (IPDs) 236 may include resistors, capacitors, inductors, and other passive elements into a single package and are configured to provide various functions, such as decoupling, biasing, filtering, matching, transforming, or combinations thereof. In some embodiments, underfill material and protective film may be formed over the integrated passive devices (IPDs) 236.

As shown in FIG. 5, a plurality of first packages 202 are formed over the carrier substrate 210 after the operation 108. In operations 110-116, a plurality of second packages 204 are stacked on the first packages 202 to form a plurality of semiconductor device packages 200, which are InFO-PoP packages.

In operation 110, the carrier substrate 210 is de-bonded, and the structure is then flipped over and placed on a tape 238, as shown in FIG. 6. A carrier substrate de-bonding process is performed to detach (de-bond) the carrier substrate 210 from the backside redistribution structure 212, e.g., polymer buffer layer 218. In accordance with some embodiments, the de-bonding includes projecting a light such as a laser light or an UV light on the release layer 216 so that the release layer 216 decomposes under the heat of the light and the carrier substrate 210 can be removed. The structure is then flipped over and placed on the tape 238.

Openings 2180 are formed through the polymer buffer layer 218 to expose portions of the metallization pattern 220. The openings 2180 may be formed, for example, using laser drilling, etching, or the like. The second packages 204 are attached to the metallization pattern 220 in the package region 202A, 202B.

In some embodiments, each of the second packages 204 may include a substrate and one or more stacked dies coupled to the substrate. In some embodiments, the second package 204 may include a single die, for example a DRAM chip. In other embodiments, the second package 204 may include a stack of dies. For example, the second package 204 may include a DRAM package including one or more DRAM dies. In some embodiments, the second package 204 includes connectors 240 configured to bond with the first packages 202. The connectors 240 may be similar to the conductive connectors 234 described above and the description is not repeated herein, although the connectors 240 and the conductive connectors 234 need not be the same.

In some embodiments, the second package 204 may be coupled to the integrated circuit die 224, connectors 240, the metallization pattern 220, and the through vias 214. The second package 204 may be disposed in over the package regions 202A, 202B with the connectors 240 aligned with the metallization pattern 220. A reflow process may be applied to adhere the connectors 240 to the metallization pattern 220.

Even though the first packages 202 and the second package 204 are joint together by the metallization pattern 220 and the connectors 240, the jointed structure may be under stress and venerable to break due to the different coefficients of thermal expansion (CTEs) between the first package 202 and the second package 204. Particularly, stress may be concentrated at the neck of the connectors 240 causing breakage. An underfill is applied between the first package 202 and the second package 204, surrounding the connectors 240 to enhance the jointed structures. The underfill may be applied by flowing a curable material in the gap between the first package 202 and the second package 204 by capillary flow, and then cure the underfill in place. The cured underfill functions as a glue to enhance the jointed structures. However, it has been observed that bubbles may remain in the underfill. Stress caused by different coefficients of thermal expansion (CTEs) is concentrated around the air bubbles. The uncontrolled force around the bubbles reduces reliability of the semiconductor device packages. The bubbles may burst under heat or reduced external pressure.

Embodiments of the present disclosure provide a method of forming an underfill between two packages with reduced bubbles, therefore, with improved reliability.

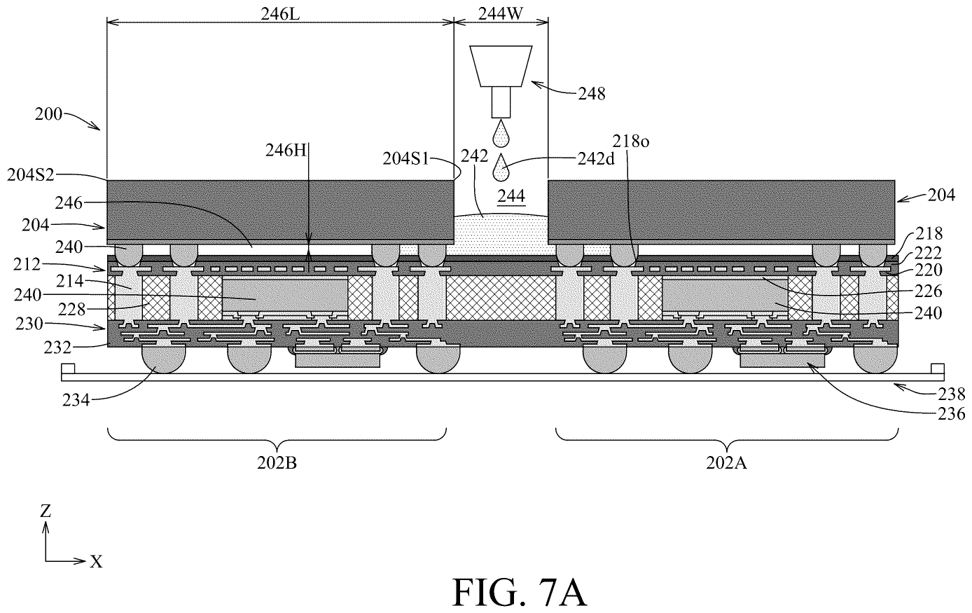

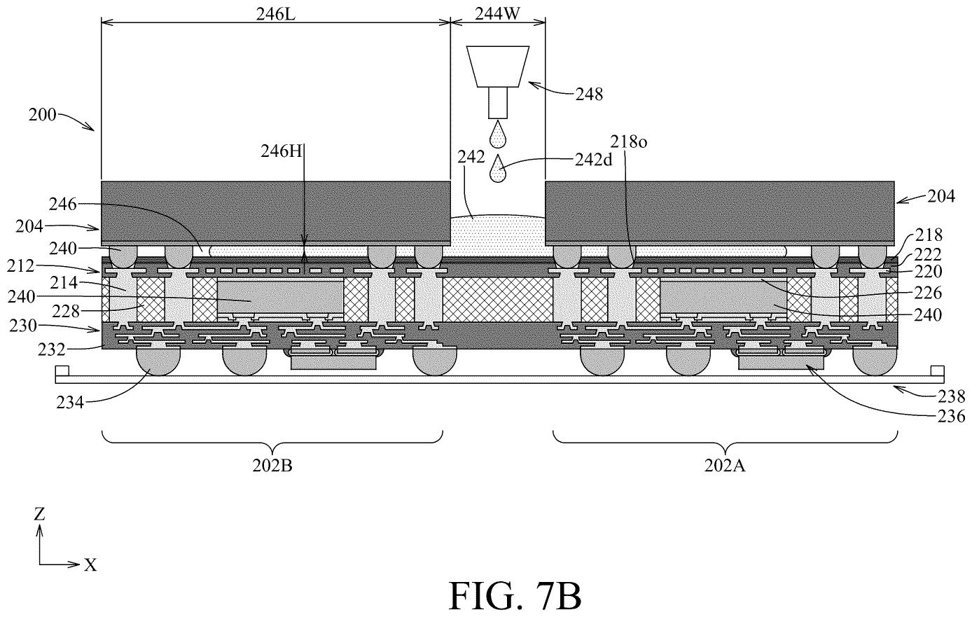

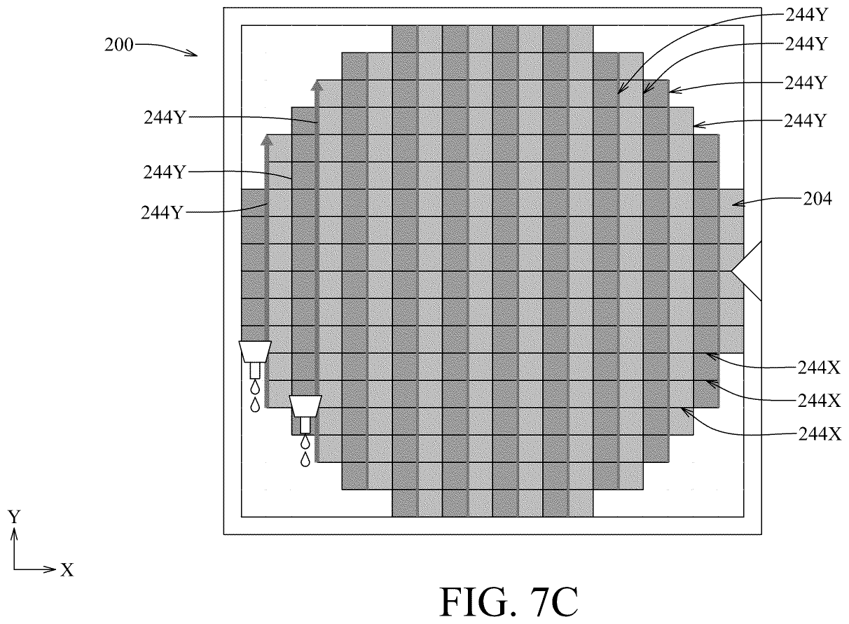

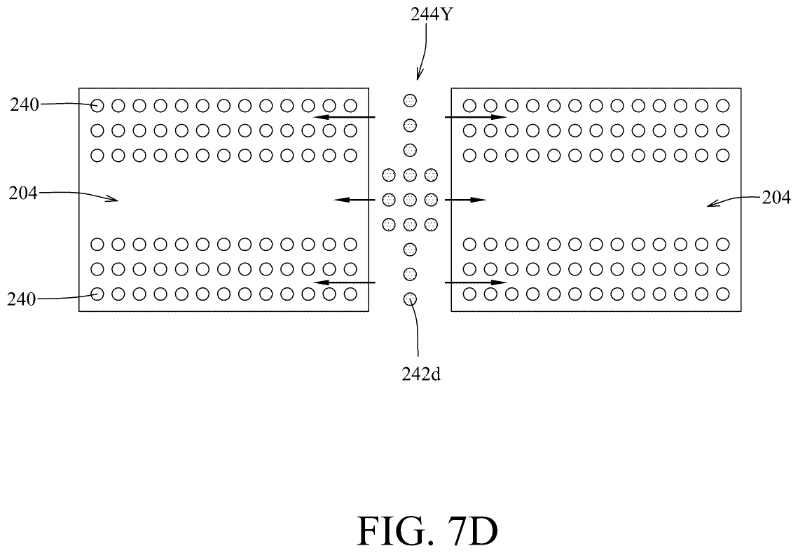

In operation 112 of the method 100, an underfill 242 is applied between the second package 204 and the first package 202 as shown in FIGS. 7A, 7B, 7C, and 7D. The underfill 242 is applied between the first package 202 and the second package 204, surrounding the connectors 240. The underfill 242 may be applied by any suitable methods. In some embodiments, the underfill 242 is applied to between the second package 204 and the first package 202 from scribe regions 244 between the neighboring second packages 204. As shown in FIG. 7A, the first packages 202 are connected to each other by the front-side redistribution structure 230, the backside redistribution structure 212, and the encapsulant layer 228 while the second packages 204 are discretely disposed over the first packages 202 with the scribe regions 244 between neighboring second packages 204.

In some embodiments, the underfill 242 is applied using a dispense system 248 to dispense droplets 242d flowing from the scribe regions 244 to the polymer buffer layer 218 between the first packages 202. The scribe regions 244 may have a width 244 W between the neighboring second packages 204. In some embodiments, the width 244 W between the neighboring second packages 204 is in arrange between 200 μm and about 1000 μm, for example about 400 μm. The underfill 242 then fills by capillary action gaps 246 between the first package 202 and the second package 204, as shown in FIGS. 7A and 7B. A height 246H in the gap 246 between the first package 202 and the second package 204 may be between about 100 μm and about 800 μm, for example between about 100 μm and about 200 μm.

In some embodiments, after the underfill 242 is dispensed, heating process may be performed to facilitate capillary flow of the underfill material. The underfill material flows between the first package 202 and the second package 204 by capillary action. In some embodiments, surfaces of the second package 204 and the first package 202 may be activated by exposing the surfaces to a plasma before the first underfill material is dispensed, for example, before operation 110, to increase the wettability of the surfaces and improve the capillary action of the underfill material.

The underfill 242 may be any acceptable material, such as a polymer, epoxy, molding underfill, or the like. In some embodiments, the underfill material may include an epoxy material, one or more filler, one or more hardener, one or more catalyst, and one or more coupling agents. The epoxy material may be any liquid epoxy resin, such as DEGEBA (Bisphenol A diglycidyl ether), capable of providing adhesion and with suitable mechanical properties. The one or more filler may be SiO₂, Al₂O₃, or the like. The one or more filler is used to decrease CTE and to increase rigidity of the underfill material. The one or more hardeners may be phenol novolac, amine, anhydride, or the like. The one or more hardeners are configured to facilitate linear and/or cross polymerization. The one or more catalyst may be nitrogen compounds, phosphorus compounds, or the like. The one or more catalysts are configured to enhance rate of polymerization, reduce cycle and cure time. The one or more coupling agents may be silane compound, or the like. The one or more coupling agents are configured to increase the tightness between the epoxy and filler. The composition of the underfill material may be adjusted to obtain desired properties. For example, the composition of the underfill material may be selected to obtain desirable modulus, glass transition temperature (Tg), CTE. (a1) at temperature under Tg, CTE (a2) at temperature above Tg, and viscosity η.

For example, to improve workability of the underfill material, it is desirable to have fast flow during application. Flow time of the underfill material is a function of the viscosity η, underfill distance L, surface tension γ of the underfill material, gap height h, and contact angle θ between the underfill material and the first package:

$$T = \frac{2 η {L}^{2}}{h γ cos θ}$$

Thus, to improve workability, it is desirable to have low viscosity, high surface tension, and small contact angle.

The underfill 242 may be selected to have a viscosity to allow the underfill 242 to flow between the first package 202 and the second package 204 that the gaps 246 are completely filled and the connectors 240 are surrounded. In some embodiments, the underfill 242 may have a viscosity of between about 100 Pa·s and about 200 Pa·s, such as about 150 Pa·s.

In another example, to improve underfill reliability, such as to improve protection and elimination delamination. To improve protection, such as protection to the connectors 240, it is desirable to have high glass transition temperature Tg. To eliminate delamination, it is desirable to have a low glass transition temperature Tg and low modulus.

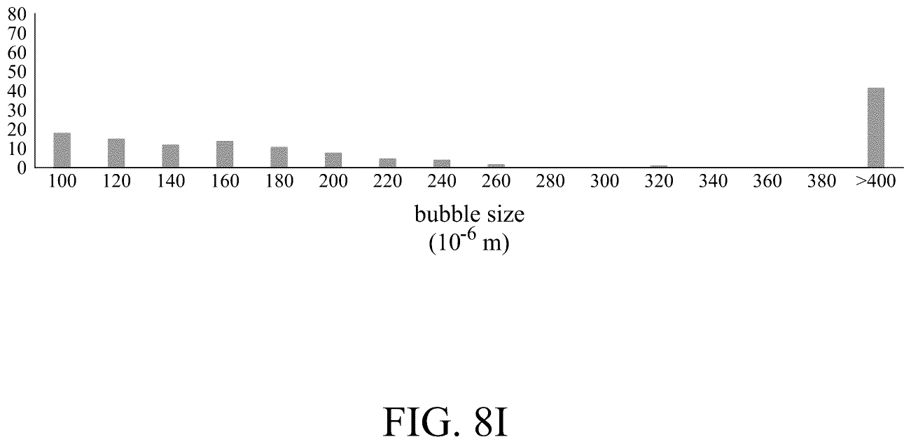

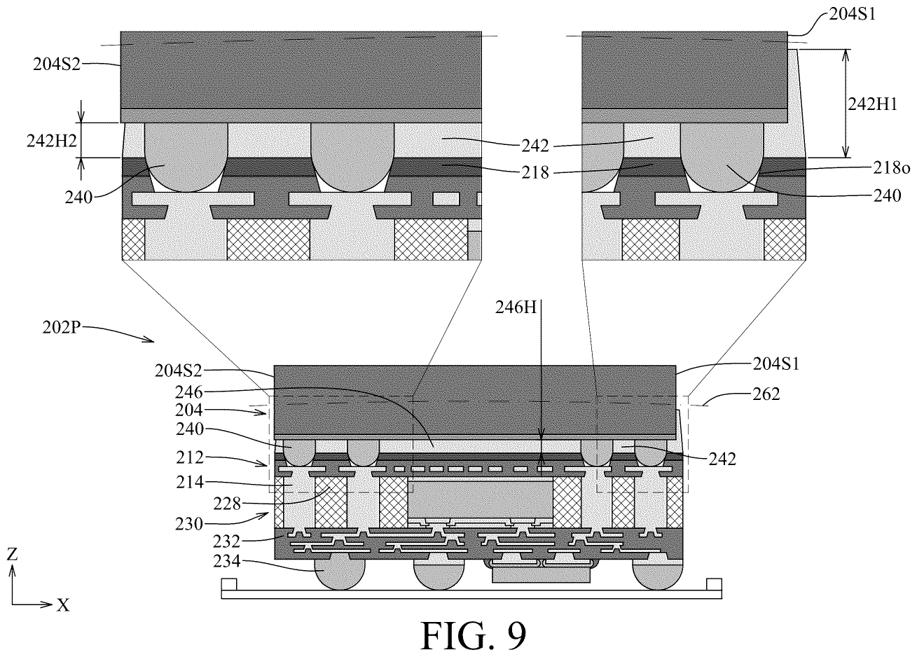

In another example, depending on the CTE value of the underfill after glass transition, relative to the CTE of the first package 202, the device structure may have a convex or concaved profile. For example, when the CTE value of underfill 242 is lower than the CTE of the first package 202, the device structure will have a convex profile (as shown in FIG. 9) after the underfill 242 is cured. On the other hand, when the CTE value of underfill 242 is higher than the CTE of the first package, the device structure will have a concaved profile after the underfill 242 is cured.

In some embodiments, the underfill material may be dispensed along every other scribe lines along on directions, or along alternate scribe lines. FIG. 7C is a schematic top view of the semiconductor device package 200. As shown in FIG. 7C, the second packages 204 are arranged over the first packages 202, which are arranged in an array over the frame. The scribe regions 244 include a plurality of vertical scribe lines 244Y and a plurality of horizontal scribe lines 244X intersecting with the plurality of vertical scribe lines 244Y. In some embodiments, the underfill material is disposed by the dispense system 248 along the vertical scribe lines 244Y. Particularly, the underfill material is dispensed along very other vertical scribe lines 244Y. As the underfill 242 is dispensed into one of the scribe lines 244Y shown in FIG. 7A, the underfill 242 flows under capillary action along the x-direction towards the neighboring scribe lines 244Y shown in FIG. 7B. By dispensing the underfill 242 only along every other scribe line along one direction, embodiments of the present disclosure prevent any air bubbles from trapped in the gap 246 between the first package 202 and the second package 204. The underfill 242 flows for a distance 246L from one scribe line 244Y through the gap 246 between the first package 202 and the second package 204 to the neighboring scribe line 244Y for a distance 246L.

In some embodiments, the underfill material may be dispensed at non-uniform amount along the scribe lines. In some embodiments, under the second packages 204, more droplets 242d of the underfill material are dispensed at locations of the scribe line where less connectors 240 are located and less droplets 242d are dispensed at locations of the scribe line where more connectors 240 are located. The non-uniform dispense of droplets 242d facilitates even underfill flow under the second packages 204. As shown in FIG. 7D, which is a partial enlarged top view of FIG. 7C showing two neighboring second packages 204 across one scribe line 244Y, the number of droplets 242d dispended at different locations on a scribe line 244Y are different. FIG. 7D also schematically illustrates distribution of the connectors 240 on the second packages 204. In this particular example, the connectors 240 are denser near a top edge and a bottom edge than a central portion of the second packages 204. Under capillary action, the underfill material flows faster in areas with denser distribution of the connectors 240 than in areas the connectors 240 are sparsely distributed.

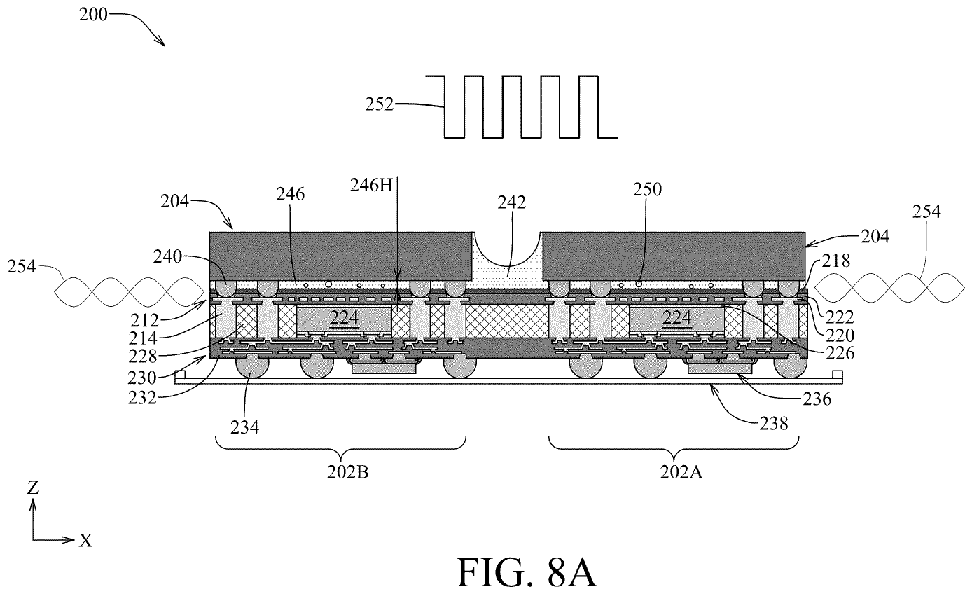

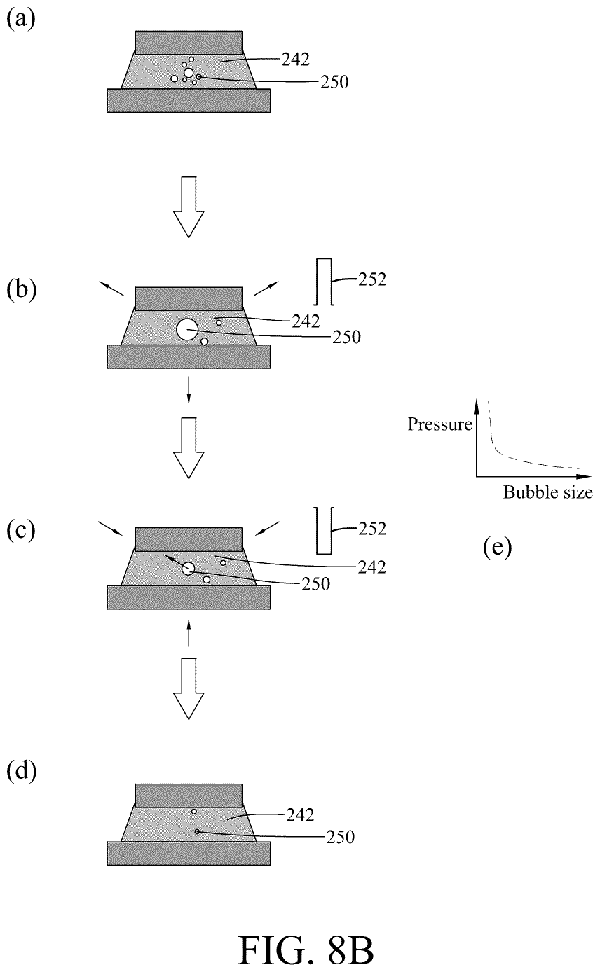

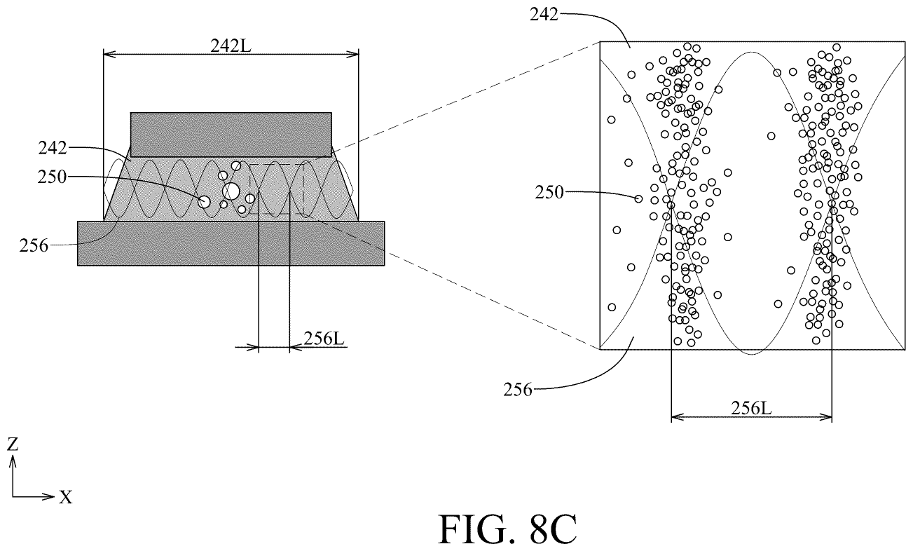

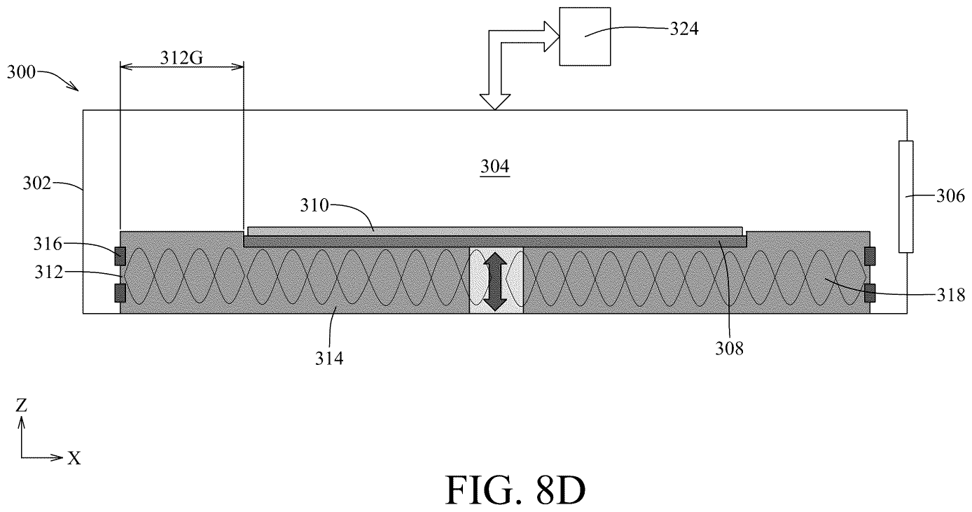

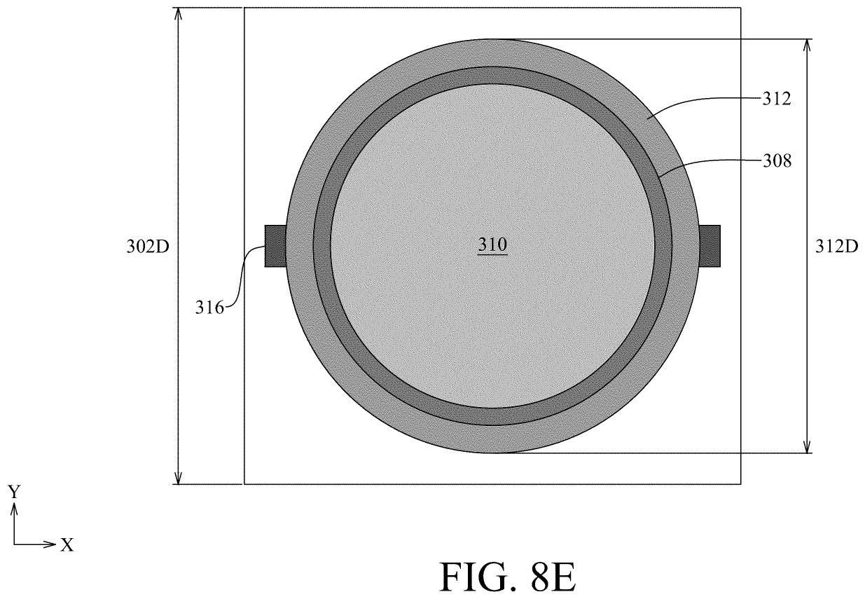

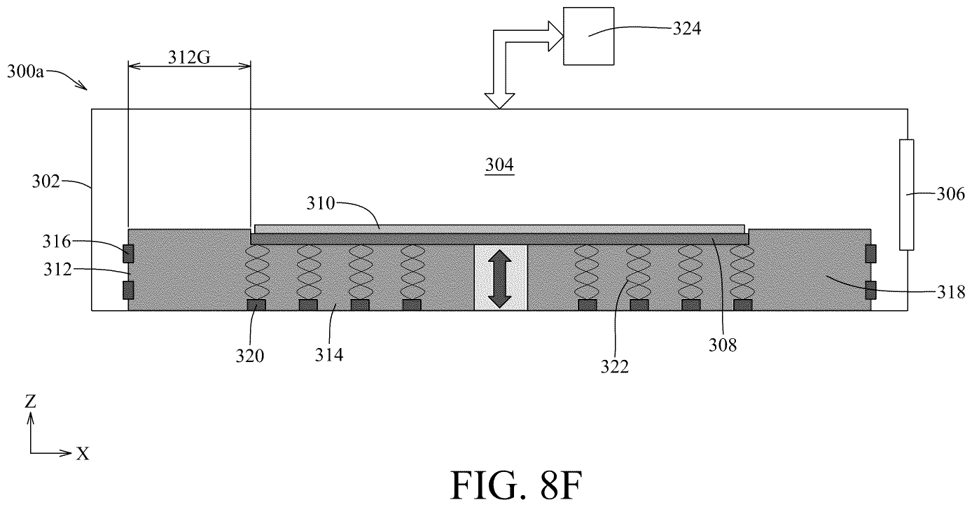

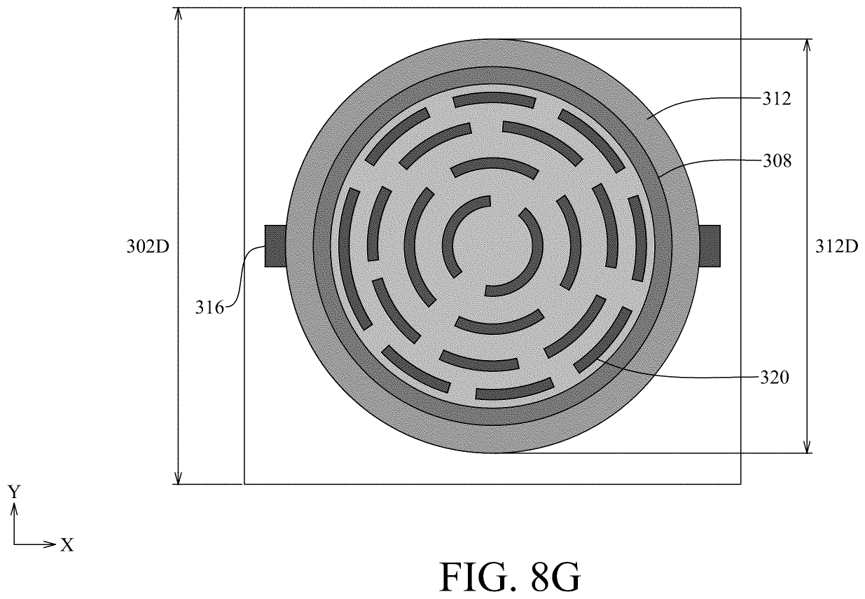

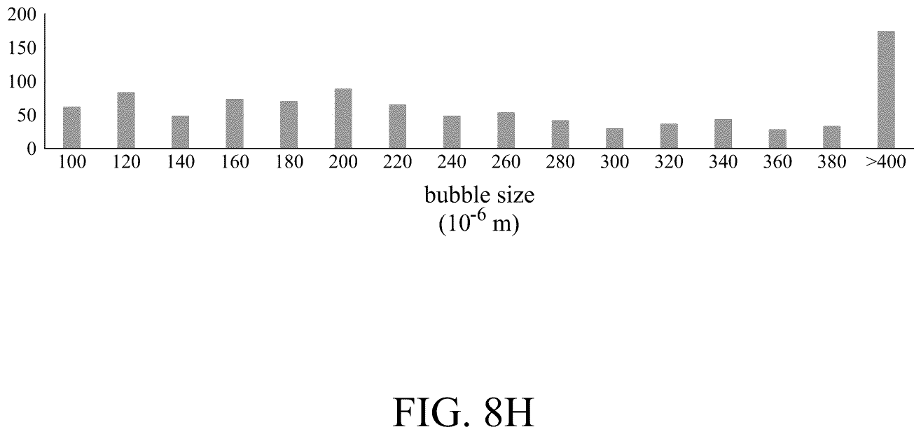

In operation 114 of the method 100, an oscillation process is performed to reduce bubbles trapped in the underfill 242, as shown in FIG. 8A-8D. As shown in FIG. 8A, after filling the gap 246 in operation 114, bubbles 250 may be trapped in the underfill 242. The bubbles 250 may burst during subsequent processing and during operation, causing damage to the device package. In some embodiments, the bubbles 250 may be removed and/or reduced in size by an oscillation process. In some embodiments, the oscillation process includes oscillating vacuum level applied to the underfill 242 before curing. In some embodiments, the oscillation process may include applying an acoustic oscillation 254 to the underfill 242.

Embodiments of the present disclosure provide a method of dissipating bubbles in the underfill by moving the bubbles with pressure oscillation. It has been observed that sizes of bubbles remaining in the underfill 242 change with the pressure applied to the underfill 242. Particularly, size of the bubbles reduces as the external pressure increases. It also has been observed that as the size of the bubble increases, it becomes easier for the bubble to dissipate. The following formula reflects a terminal velocity of a bubble in a liquid, such as the underfill 242 prior to curing.

$${v}_{t} = \frac{2 g ( {ρ}_{L} - {ρ}_{air} )}{9 η} {r}^{2}$$

Where P is bubble pressure, V is bubble volume, r is bubble radius, β_{L} is density of liquid, βₐᵢᵣ is density of bubble, g is the acceleration of gravity, η is the Viscosity of liquid. When two bubbles with volume V merge, the merged bubble has a double volume, V_{merge}=2V, the radius r increases to

$$\sqrt[3]{2} r ,$$

with PV∞n and n is unchanged, the terminal velocity of merged bubble increase with radius r.

Embodiments of the present disclosure provide a process to first increasing the bubbles sizes by reducing an exterior pressure exposed to the underfill and then applying a higher pressure to the underfill to assist the dissipation of the enlarged bubbles.

FIG. 8B schematically illustrates an oscillation process of vacuum pressure according to embodiments of the present disclosure. Graph (a) of FIG. 8B schematically illustrates state of bubbles 250 in the initial state after application of the underfill 242 between the first package 202 and the second package 204. The bubbles 250 are of various sizes. At this stage, the underfill 242 is under about atmospheric pressure. In graph (b) of FIG. 8B, the underfill 242 is exposed a low pressure level or the pressure level around the underfill 242 is reduced to a vacuum state. As the pressure reduces, the size of the bubbles 250 increases and the number of bubbles 250 reduces as adjacent bubbles 250 may merge with as their sizes increase. In graph (c) of FIG. 8B, the underfill 242 is exposed to a high pressure level or the pressure level around the underfill 242 increases. Under the increased pressure, the bubbles 250 reduces in size from the graph (b), and larger bubbles 250 may dissipate by diffusing out of the underfill 242. The process shown in graph (b) and graph (c) may be repeated. In graph (d) of FIG. 8B, the underfill 242 is out of the pressure oscillation process. Comparing graphs (d) and (a), the size and number of bubbles 250 are both reduced. In graph (e) of FIG. 8B, the relationship between the pressure and bubble size is schematically illustrated.

In some embodiments, the oscillation process may be performed in a processing chamber where interior pressure of may be controlled. The pressure levels may be selected according to properties of the underfill 242 being processed. In some embodiments, the pressure levels may oscillate in a range between about 0.001 atmosphere and about 10 atmospheres, for example between about 0.1 atmosphere and about 1.0 atmosphere. In some embodiments, the vacuum pressure oscillation process includes reducing a chamber pressure to a first level for a first period of time and then increasing the chamber pressure to a second level for a second period time. In some embodiments, the first pressure level is in a range between about 0.001 atmosphere and about 0.1 atmospheres. The first period of time is in a range between about 10 seconds and about 60 seconds. The first pressure level is in a range between about 1.0 atmosphere and about 10.0 atmospheres. The second period of time is in a range between about 10 seconds and about 60 seconds. If necessary, reducing chamber pressure and increasing chamber pressure may be performed two or more cycles to achieve desired bubble reduction level. In some embodiments, when multiple cycles of pressure oscillation are performed, the pressure levels and/or duty cycles may vary between cycles. In some embodiments, a ratio of the first pressure (low pressure) over the second pressure (high pressure) is in a range between about 5% and about 25%, for example, between about 10% and about 20%.

In some embodiments, the oscillation process may include applying an acoustic oscillation 254 to the underfill 242. In some embodiments, the acoustic oscillation 254 may be performed by applying an acoustic standing wave across the underfill. FIG. 8C schematically illustrates the bubble merge in reaction to the acoustic standing wave 256. As shown in FIG. 8C, a standing wave 256 is applied across a length 242L of the underfill 242. Upon application of the acoustic standing wave 256, the bubbles 250 gathers along a line between peak and trough of the acoustic standing wave 256. Not meant to be bound by theory, the acoustic standing wave 256 applies an oscillating pressure along the length 242L of the underfill 242, and drives the bubbles 250 towards low pressure regions, or regions in the underfill 242 near the valley of the acoustic standing wave 256. The gathered bubbles 250 are more likely to merge under the pressure oscillation 252 discussed above.

In some embodiments, the acoustic standing wave 256 is selected so that the length 242L is greater than a half wavelength 256L of the acoustic standing wave 256. In other words, the frequency of the standing waving 256 is selected in a range so that the half wavelength 256L of the acoustic standing wave 256 is shorter than the length of the underfill 242. In some embodiments, the acoustic standing wave 256 is in a frequency in a range between about 20 kHz to about 2 MHz, for example, between about 20 KHz and about 500 kHz. In some embodiments, the acoustic standing wave 256 has a magnitude in a range between about 5000 N/m² and about 50000 N/m².

The acoustic oscillation 254 may be applied to increase merging of the bubbles 250 in the underfill 242. In some embodiments, the acoustic oscillation 254 may be applied by generating an acoustic standing wave in a medium and positioning the underfill 242 in the medium. In some embodiments, the medium may be deionized water.

In some embodiments, the pressure oscillation 252 and the acoustic oscillation 254 may be performed in the same processing chamber. FIGS. 8D-8E schematically illustrate a process chamber 300 for operation 116. FIG. 8D is a schematic cross section view of the process chamber 300. The process chamber 300 includes a chamber housing 302 defining an inner volume 304. A substrate chuck 308 is disposed in the inner volume304 of the chamber housing 302 and configured to secure and support a substrate, for example, the tape 238 with the semiconductor device package 200 disposed thereon. The substrate chuck 308 may be a vacuum chuck or an electrostatic chuck (e-chuck). The chamber housing 302 further includes a slit valve door 306. The slit valve door 306 may open to allow passages of substrates being processed and close to seal the inner volume 304. A pressure control unit 324 may be fluidly connected to the inner volume 304 and configured to vacuum and pressurize the inner volume 304. The pressure control unit 324 may be controlled to generate the pressure oscillation 252 in the inner volume 304.

If the acoustic oscillation 254 is to be performed in operation 116, the process chamber 300 may further include a basin 312 configured to retain a liquid medium 314 therein. The substrate chuck 308 may be selectively positioned to be in contact with the liquid medium 314. In some embodiments, the substrate chuck 308 may move upward and downward to selectively position the substrate 310 to be in contact the liquid medium 314. In some embodiments, the liquid medium 314 is DI water. Alternatively, the liquid medium 314 may be any suitable liquid. In some embodiments, acoustic sources 316 are attached to the basin 312. The acoustic sources 316 are configured to generate a standing wave in the liquid medium 314.

FIG. 8E is a schematic top view of the process chamber 300 showing the substrate chuck 308 and the basin 312 according to embodiments of the present disclosure. As shown in FIG. 8E, in some embodiments, the basin 312 and the substrate chuck 308 are both circular in shape. The substrate chuck 308 is disposed at a center of the basin 312. The substrate chuck 308 has a diameter 308D. In some embodiments, the diameter 308D is in a range between about 350 mm and 450 mm, for example about 400 mm. The basin 312 has a diameter 312D. The diameter 312D is greater than the diameter 308D. In some embodiments, the diameter 312D is greater than the diameter 308D for a gap of 312G. In some embodiments, the gap 312G is in a range between about 5% and about 10% of the diameter 308D. In some embodiments, the diameter 312D is in a range between about 400 mm and 500 mm, for example about 500 mm. In some embodiments, the gap 312G is in a range between about 35 mm and about 50 mm, for example about 40 mm.

In some embodiments, the process chamber 300 includes two acoustic sources 316 disposed in one line along a diameter of the basin 312. For example, two acoustic sources 316 disposed along a central line of the basin 312 along the x-direction. The acoustic sources 316 are configured to generate a standing wave 318 in the liquid medium 314. The standing wave 318 is along the x-direction. During operation, the substrate chuck 308 may be lowered to be in contact with the liquid medium 314. The standing wave 318 is then transferred to the liquid, such as the uncured underfill 242 on the substrate 310 disposed on the substrate chuck 308. In some embodiments, the substrate 310 is not in contact with the liquid medium 314.

The process chamber 300 is configured to generate a standing wave 318 propagating along the x-direction. By arranging or adding acoustic source at other locations, standing waves moving along other directions may be generated in the liquid medium 314, thus, providing alternative process results. FIGS. 8F and 8G schematically illustrate a process chamber 300a according to another embodiment of the present disclosure. The process chamber 300a is similar to the process chamber 300 except that the process chamber 300a includes a plurality of acoustic sources 320 disposed on a bottom of the basin 312. The acoustic sources 320 are configured to generate a standing wave 322 in the liquid medium 314. The standing wave 322 is along the y-direction. During operation, the substrate chuck 308 may be lowered to be in contact with the liquid medium 314. The standing wave 322 is then transferred to and established in the liquid content in the substrate 310 disposed on the substrate chuck 308. For example, the standing wave 322 is transferred to and established in, the uncured underfill 242 on the substrate 310 disposed on the substrate chuck 308. The standing wave 322 is at a higher frequency that the standing wave 318 in order to sustain a standing wave within the height 246H of the gap 246 in which the underfill 242 is disposed.

In some embodiments, as shown in FIG. 8G, the plurality of acoustic sources 320 may be arranged in a concentric array. The concentric array may provide azimuthal process uniformity. In some embodiments, the acoustic sources 316 and the acoustic sources 320 may be used alternatively during the operation. In some embodiments, the acoustic sources 316 may be omitted in the process chamber 300a.

In some embodiments, the pressure oscillation 252 may be performed without the acoustic oscillation 254. In some embodiments, the acoustic oscillation 254 and the pressure oscillation 252 may be performed simultaneously. In other embodiments, the acoustic oscillation 254 may be selectively performed during a portion of the duty cycle of the pressure oscillation 252. For example, the acoustic oscillation 254 may be performed during the low pressure period in the duty cycle to assist bubble merging, and off the high pressure period in the duty cycle to avoid interference with bubble dissipation. In yet in another embodiments, the acoustic oscillation 254 and the pressure oscillation 252 may be performed sequentially.

The oscillation process reduces the number of bubbles and reduces mean bubble sizes. FIG. 8H includes an exemplary graph of bubble counts of various bubble sizes without the oscillation process. FIG. 8I includes an exemplary graph of bubble counts of various bubble sizes with oscillation process. It has been observed, from the examples in FIGS. 8H and 8I, that after the oscillation process with acoustic oscillation and vacuum pressure oscillation, the mean bubble size in the underfill 242 has reduced from 40 μm to about 0.02 μm, and the number of bubbles has reduced from about 797 in a unit area to about 90 in a unit area. Furthermore, comparing the graphs in FIGS. 81 and 8H, it is observed that the number of large size bubbles is reduced from 174 to 42 as a result of bubble merging from the oscillation process.

In operation 116 of the method 100, after oscillation process, the underfill 242 may be cured. The underfill 242 may be cured at room temperature, or by applying heat or ultra-violet (UV) light.

In operation 118 of the method 100, a singulation process is performed by sawing along the scribe lines 244X and 244Y (FIG. 7C) between adjacent package regions 202A and 202B. The sawing singulates the package region 202A from the package region 202B. FIG. 9 illustrates a resulting package 202P. The package 202P may also be referred to as an InFO-POP package. In some embodiments, the underfill 242 may be selected to have after glass transition CTE to enable a curved profile 262 in the package 202P. In some embodiments, the curved profile is a convex profile, as shown in FIG. 9.

Referring back to FIGS. 7A and 7C, because the underfill 242 is applied through every other scribe line 244Y along the Y-direction, the underfill 242 is filled at a higher level on a sidewall 204S1 which faces the scribe line 244Y with being dispensed with droplets 242d than on other sidewalls 204S2. For every second package 204, only one sidewall 204S1 is facing the scribe line 244Y where the droplets 242d are dispensed. As shown in FIG. 9, the underfill 242 on the sidewall 204S1, which faces the dispensed scribe line 244Y, has a height 242H1 along the z-direction from a top surface of the first package 202, i.e. the top surface of the polymer buffer layer 218. The underfill 242 on the sidewall 204S2, which does not face the dispensed scribe line 244Y, has a height 242H2 along the z-direction from a top surface of the first package 202, i.e. the top surface of the polymer buffer layer 218. The height 242H1 is greater than the height 242H2. In some embodiments, the height 242H2 is in a range between about 100 μm and about 800 μm, for example between about 100 μm and about 200 μm. The height 242H1 is in a range between about 200 μm and about 2000 μm, for example between about 800 μm and about 1600 μm.

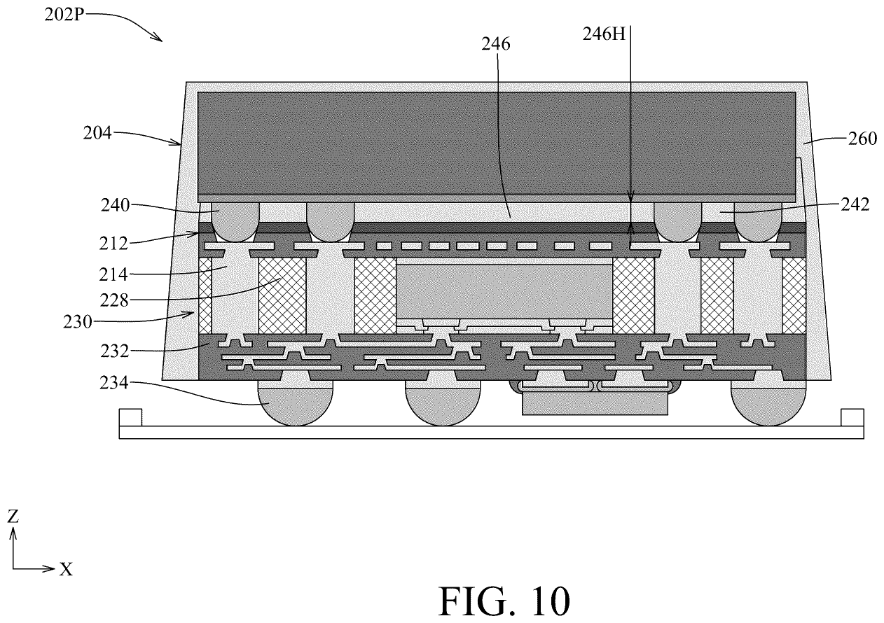

In some embodiments, as shown in FIG. 10, a molding layer 260 may be applied over the underfill 242 and the second packages 204 to provide further protection to the package 202P. In some embodiments, the molding layer 260 may be a molding compound, epoxy, or the like. The molding layer 260 may be applied by compression molding, transfer molding, or the like. The molding layer 260 may be formed over the package 202p and then cured.

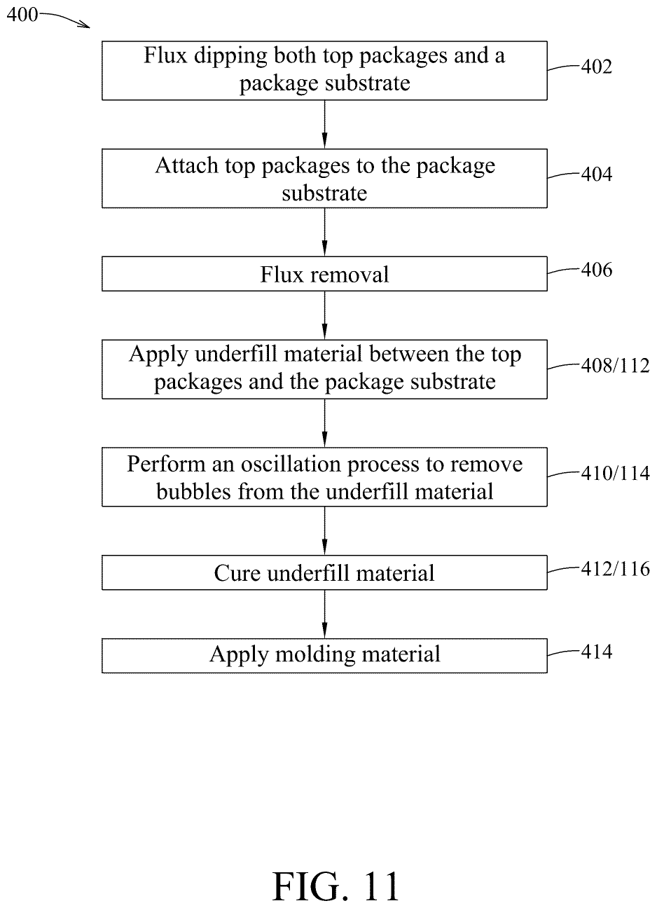

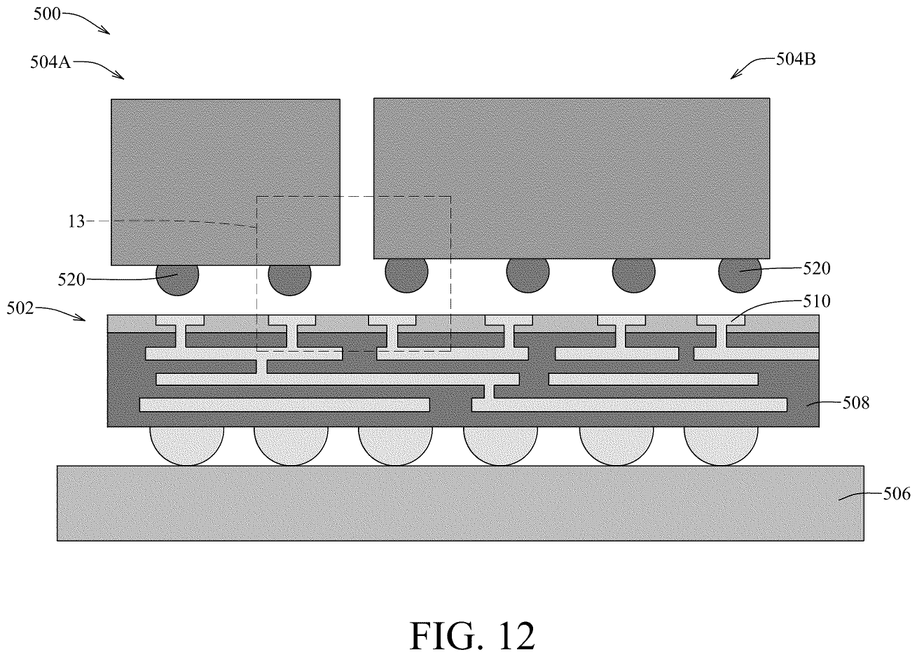

The method of forming underfill layers described in operations 112, 114 and 116 may be used in any packaging process to reduce bubbles in the underfill material. FIG. 11 is a flow chart of a method 400 for forming a CoWoS package according to embodiments of the present disclosure. FIGS. 12, 13A-13F, and 14 illustrate intermediary stages of fabricating the CoWoS package 500 in accordance with some embodiments.

FIG. 12 schematically illustrates components for the CoWoS package 500. Particularly, the CoWoS package 500 includes a package substrate 502 and one or more top packages 504A and 504B to be bonded with the package substrate 502.

The package substrate 502 may include a substrate 506 and an interposer 508 attached thereon. The substrate 506 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate 506 may be an SOI substrate. Generally, an SOI substrate includes a layer of a semiconductor material such as epitaxial silicon, germanium, silicon germanium, SOI, SiGe-on-insulator (SGOT), or combinations thereof. The substrate 506 is, in one alternative embodiment, based on an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for package substrate 502.

The interposer 508 may include active and passive devices (not shown). As one of ordinary skill in the art will recognize, a wide variety of devices such as transistors, capacitors, resistors, combinations of these, and the like may be used to generate the structural and functional requirements of the design for the top packages 502A, 502B. The devices may be formed using any suitable methods.

The interposer 508 may also include metallization layers and vias (not shown) and contact pads 510 over the metallization layers and vias. The metallization layers may be formed over the active and passive devices and are designed to connect the various devices to form functional circuitry. The metallization layers may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). In some embodiments, the package substrate 502 is substantially free of active and passive devices.

The top packages 504A, 504B may be chip-on-wafer (CoW) packages. In some embodiments, the top package 504A/504B may include a die stack attached to a wafer. The die stack may be for various functions, such as a die stack as graphics processing unit (GPU), a high bandwidth memory (HBM), or a system on chip (SoC) or the like. In some embodiments, the top package 504A includes a HBM die stack and the top package 504B includes a SOC die stack.

Conductive connectors 520 are formed on the top packages 504A, 504B. The conductive connectors 520 are connected to features, e.g., logic devices, interposers on the wafers of the top package 504A, 506B. The conductive connectors 520 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like.

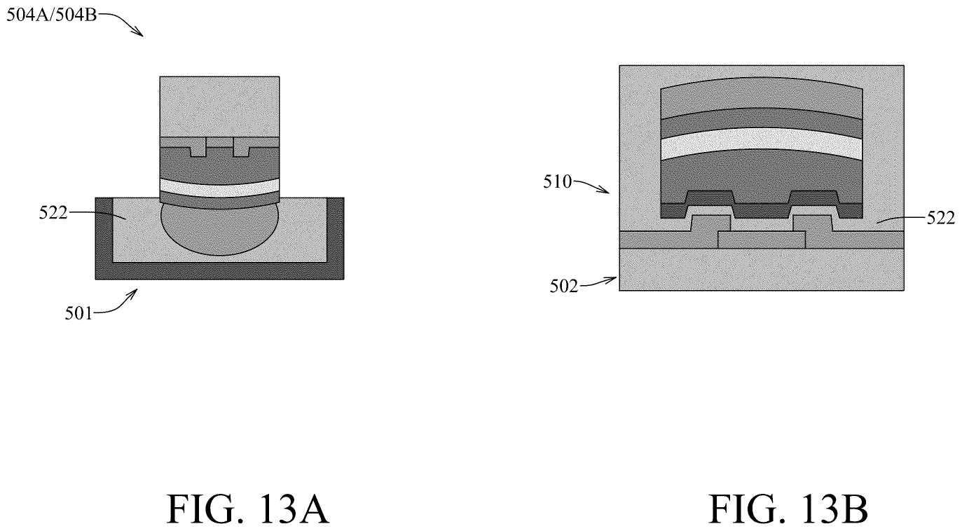

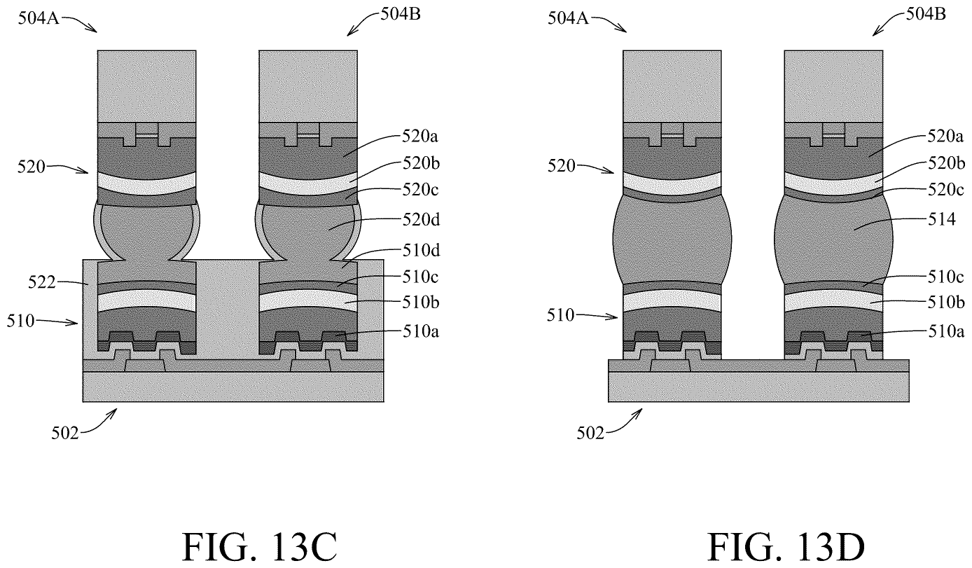

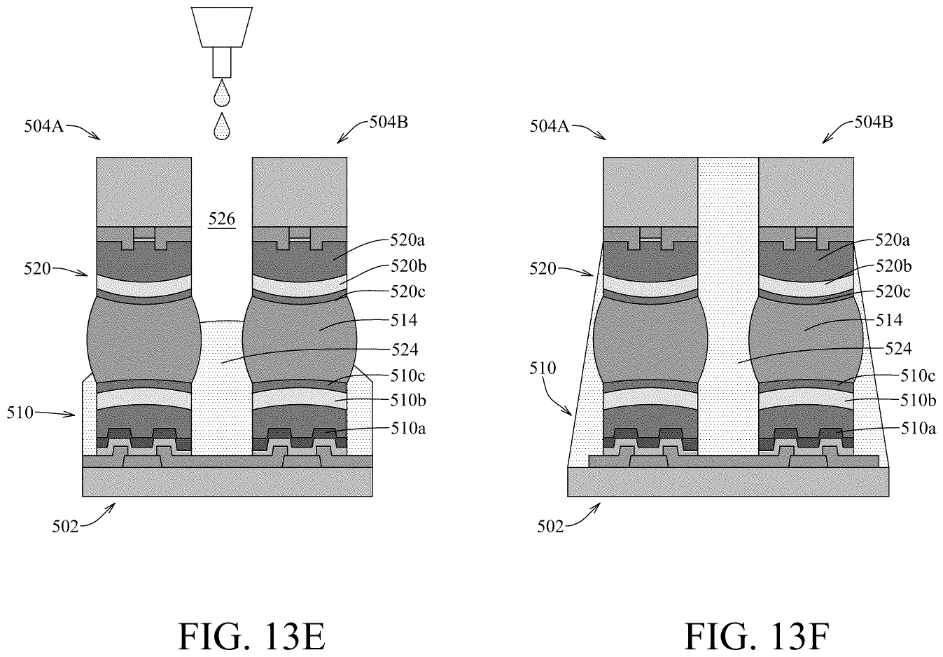

During packaging, the conductive connectors 520 are aligned with the contact pads 510 and then reflowed to electrically and physically couple the package substrate 502 and the top packages 504A, 504B. FIGS. 13A-13F schematically illustrate an enlarged region 13 in FIG. 12 to show the process of bonding the top packages 504A, 504B to the package substrate 502.

In operation 402 of the method 400, a flux dipping process is performed, as shown in FIGS. 13A, 13B, and 13C. The conductive connectors 520 on the top packages 504A, 504B are dipped into a flux material 522, as shown in FIG. 13A. The contact pads 510 on the package substrate 502 is applied with the flux material 522, as shown in FIG. 13B. The flux material 522 in a conductive paste such as solder paste, silver paste, or the like. FIG. 13C also illustrates details of the contact pad 510 and the conductive connectors 520. The contact pad 510 may include four layers, a first layer 510a comprising a first metal, such as copper, a second layer 510b comprising a second metal, such as nickel, a third layer 510c comprising a metal, such as copper, and a top layer 510d comprising an intermetallic compound (IMC). Similarly, the conductive connector 520 may include four layers, a first layer 520a comprising a first metal, such as copper, a second layer 520b comprising a second metal, such as nickel, a third layer 520c comprising a metal, such as copper, and a top layer 520d comprising an IMC.

In operation 404 of the method 400, the conductive connectors 520 are bonded to the contact pads 510 as shown in FIG. 13D. The conductive connectors 520 and the corresponding contact pads 510 are aligned. Then a reflow process is performed to bond the conductive connectors 520 with the corresponding contact pads 510. The IMC containing top layers 510d and 520d are bonded together forming one joint layer 514.

In operation 406 of the method 400, the flux material 522 is removed between the package substrate 502 and the top packages 504A, 504B leaving a gap for underfill, as shown in FIG. 13D.

In operation 408 of the method 400, a underfill material 524 is dispensed in a gap 526 between the top packages 504A and 504B and flown between the package substrate 502 and the top packages 504A, 504B by capillary action, as shown FIG. 13E. The operation 408 is substantially similar to the operation 112 of the method 100 described above.

In operation 410 of the method 400, an oscillation process is performed to reduce bubbles in the underfill material 524. The oscillation process is similar to the oscillation process of the operation 114 of the method 100 described above.

In operation 412, after reducing bubbles, the underfill material 524 is cured, as shown in FIG. 13F.

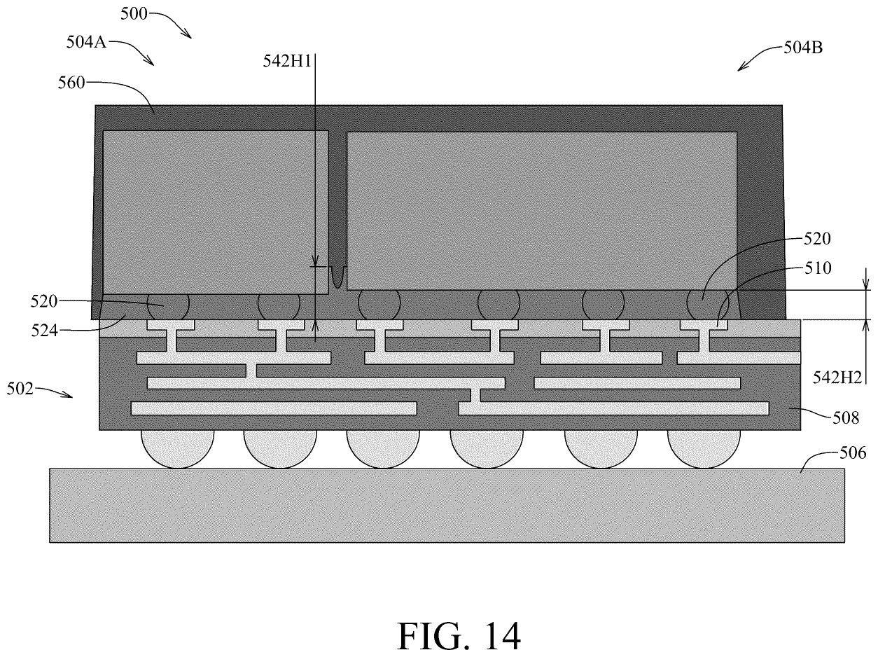

In operation 414, a molding layer 560 is formed over the underfill 242 and the top packages 504A, 504B, as shown FIG. 14. The molding layer 560 may be applied, cured, and the polished to leave a planar surface above the top packages 504A, 504B. In some embodiments, the molding layer 560 may have a thickness between about 20 microns to about 100 microns above the top packages 504A, 504B. The molding layer 560 covers sidewalls of the top packages 504A, 504B, and over the underfill material 524. In some embodiments, the underfill material 524 may have different heights on sidewalls of the top packages 504A, 504B. For example, the underfill material 524 on the sidewall facing the dispensing gap 526 has a height 542H1 along the z-direction from a top surface of the package substrate 502. The underfill 542 on the sidewalls, which does not face the dispensed gap 526, has a height 542H2 along the z-direction from a top surface of the package substrate 502. The height 542H1 is greater than the height 542H2. In some embodiments, the underfill 542 in the dispensing gap 526 may have a U-shape profile as shown in FIG. 14.

Embodiments of the present disclosure reduce bubbles in underfill structures. The method has a high throughput and improves packaging quality.

Some embodiments of the present provide a method, comprising: providing a first package having a plurality of first conductors on a first surface; providing a second package having a plurality of second conductors protruding from a second surface; attaching the first package to the second package by bonding the plurality of first conductors to the plurality of second conductors, wherein a gap is formed between the first surface and the second surface; applying an underfill material between the first surface and the second surface; oscillating the underfill material; and curing the underfill material.

Some embodiments of the present disclosure provide a method, comprising: exposing a plurality of first connectors on a first package; attaching a plurality of second packages on the first package by bonding second connectors on the second packages to the plurality of first connectors, wherein the plurality of second packages separated from one another by two or more first scribe lines along a first direction and two or more second scribe lines along a second direction; dispensing droplets of an underfill material along alternate one of the two or more first scribe lines to flow the underfill material in gaps between the first package and the plurality of second packages; and curing the underfill material in the gaps.

Some embodiments of the present disclosure provide a process chamber, comprising: a housing defining a inner volume; a basin disposed in the inner volume and configured to retain a liquid medium; one or more acoustic sources configured to generate a standing wave in the liquid medium retained in the basin; and a substrate chuck disposed over the basin in the inner volume, wherein the substrate chuck is movable to selectively contact the liquid medium retained in the basin.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
providing a first package having a plurality of first conductors on a first surface;
providing a second package having a plurality of second conductors protruding from a second surface;
attaching the first package to the second package by bonding the plurality of first conductors to the plurality of second conductors, wherein a gap is formed between the first surface and the second surface;
applying an underfill material between the first surface and the second surface;
oscillating the underfill material; and
curing the underfill material.

2. The method of claim 1, wherein the underfill material comprises:
applying a first pressure level to the underfill material for a first period of time; and
applying a second pressure level to the underfill material for a second period of time, wherein the first pressure level is lower than the second pressure level.

3. The method of claim 2, wherein the first pressure level is in a range between about 0.001 atmosphere and 0.1 atmosphere, and the second pressure level is in a range between about 1 atmosphere and about 10 atmospheres.

4. The method of claim 2, further comprising repeatedly and alternately exposing the underfill material to the first pressure level and the second pressure level.

5. The method of claim 1, further comprising applying acoustic oscillation to the underfill material.

6. The method of claim 5, wherein applying acoustic oscillation comprises applying an acoustic standing wave to the underfill material.

7. The method of claim 6, wherein the acoustic standing wave has a frequency in a range between about 20 KHz and about 500 KHz.

8. The method of claim 5, wherein applying acoustic oscillation comprises:
positioning the first package and the second package on a substrate chuck;
generating a standing wave in a liquid medium;
contacting the substrate chuck with the liquid medium.

9. The method of claim 8, wherein the liquid medium is deionized water.

10. The method of claim 1, wherein applying the underfill material comprises:
dispensing droplets of the underfill material along one sidewall of the second package and allowing the droplets to enter the gap by capillary action.

11. The method of claim 10, wherein the droplets are dispensed at varied density along the sidewall.

12. A method comprising:
exposing a plurality of first connectors on a first package;
attaching a plurality of second packages on the first package by bonding second connectors on the second packages to the plurality of first connectors, wherein the plurality of second packages separated from one another by two or more first scribe lines along a first direction and two or more second scribe lines along a second direction;
dispensing droplets of an underfill material along alternate one of the two or more first scribe lines to flow the underfill material in gaps between the first package and the plurality of second packages; and
curing the underfill material in the gaps.

13. The method of claim 12, further comprising, prior to curing the underfill material, reducing bubbles in the underfill material by varying pressure levels applied to the underfill material.

14. The method of claim 13, wherein varying the pressure levels comprise:
applying a first pressure level to the underfill material for a first period of time; and
applying a second pressure level to the underfill material for a second period of time, wherein the first pressure level is lower than the second pressure level.

15. The method of claim 12, further comprising applying an acoustic standing wave to the underfill material.

16. The method of claim 12, wherein the first package is a package substrate, and the plurality of second packages are chip-on-wafer packages.

17. The method of claim 12, wherein the first package includes a plurality of package regions, and each package region includes an integrated circuit die and through vias.

18. A process chamber, comprising:
a housing defining a inner volume;
a basin disposed in the inner volume and configured to retain a liquid medium;
one or more acoustic sources configured to generate a standing wave in the liquid medium retained in the basin; and
a substrate chuck disposed over the basin in the inner volume, wherein the substrate chuck is movable to selectively contact the liquid medium retained in the basin.

19. The process chamber of claim 18, wherein the one or more acoustic sources are positioned along a central axis on opposite sides of the substrate chuck.

20. The process chamber of claim 18, wherein the one or more acoustic sources are positioned on a bottom of the basin.
